(19) United States
(12) Patent Application Publication
(10) Pub. No.: US 2021/0366977 A1
(43) Pub. Date: Nov. 25, 2021

(54) METHOD FOR MANUFACTURING A MICROLENS

(71) Applicant: ams AG, Premstaetten (AT)

(72) Inventors: Gerhard EILMSTEINER, Premstaetten (AT); Hannes BRANDNER, Premstaetten (AT)

(21) Appl. No.: 16/772,360

(22) PCT Filed: Dec. 6, 2018
(86) PCT No.: PCT/EP2018/083824

§ 371 Date: Jun. 12, 2020

(30) Foreign Application Priority Data
Dec. 13, 2017 (EP) 17207092.2

(51) Int. Cl. H01L 27/146; G02B 3/00

(52) U.S. Cl. CPC H01L 27/14685; H01L 27/14627; G02B 3/0012

(57) ABSTRACT

A resist layer is applied on a carrier, an opening with an overhanging or re-entrant sidewall is formed in the resist layer, the carrier being uncovered in the opening, a lens material is deposited, thus forming a lens on the carrier in the opening, and the resist layer is removed.

### SUMMARY OF THE INVENTION

The method makes use of a three-dimensionally structured resist layer having an opening with an overhanging or re-entrant sidewall profile, which can be produced according to standard methods of semiconductor technology, especially using a negative photoresist and photolithography. A negative photoresist is a type of photoresist in which the portion of the photoresist that is exposed to light becomes insoluble to the developer, so that only the unexposed portion of the photoresist is dissolved by the developer.

The material that is provided for the microlense is then deposited by an evaporation technique, a sputter process or any other process that is compatible with a lift-off process. A portion of the deposited lens material forms the microlens inside the opening. The remaining portion of the deposited lens material is removed together with the residual resist by a subsequent lift-off process.

The method comprises applying a resist layer on a carrier, forming an opening with an overhanging or re-entrant sidewall in the resist layer, the carrier being uncovered in the opening, depositing a lens material, thus forming a lens on the carrier in the opening, and removing the resist layer. The resist layer may especially comprise a negative photoresist.

In variants of the method, the overhanging or re-entrant sidewall is formed to comprise at least one step, which provides different widths of the opening in regions of different depths of the resist layer. The overhanging or re-entrant sidewall can especially be formed to comprise a plurality of steps. In other variants of the method, the overhanging or re-entrant sidewall is smooth.

In further variants of the method, the lens material is deposited by evaporation or by sputtering, especially reactive sputtering.

In a further variant the lens material is an inorganic material.

In a further variant the carrier comprises a semiconductor substrate and a dielectric on the semiconductor substrate, and the resist layer is applied on the dielectric. The dielectric may especially comprise an intermetal dielectric, in which metal layers are embedded. The dielectric may further comprise a passivation layer, which is formed on or in the intermetal dielectric, the lens being formed above an aperture of the passivation layer.

In a further variant the lens material comprises an oxide of a metal. In this variant the lens material may especially comprise at least one oxide selected from the group consisting of SiO₂, HfO₂, Nb₂O₅ and TiO₂, for instance. Other oxides may be suitable as well. The lens material may instead be amorphous silicon or amorphous germanium, for instance.

The following is a detailed description of the method in conjunction with the appended figures. The definitions as described above also apply to the following description unless stated otherwise.

### BRIEF DESCRIPTION OF THE DRAWINGS

FIG. 1 is a cross section of a three-dimensionally patterned resist layer on a carrier.

FIG. 2 is a cross section according to FIG. 1 after the deposition of the lens material.

FIG. 3 is a cross section according to FIG. 2 after the removal of the resist layer.

FIG. 4 is a diagram of the height of the lens depending on the lateral position.

FIG. 5 is a cross section of a semiconductor device including a photodiode provided with a lens that can be formed according to the described method.

### DETAILED DESCRIPTION

FIG. 1 shows a resist layer 2 on a surface of a carrier 1. An opening 3 with an overhanging or re-entrant sidewall is formed in the resist layer 2. The opening 3 penetrates the resist layer 2, so that an area of the carrier surface is uncovered in the opening 3. In the following the term “width of the opening 3”, which refers to a specified plane parallel to the carrier surface, shall mean the maximal length of all straight lines lying in the intersection of that plane and the opening 3. Because of the overhanging or re-entrant sidewall, the width of the opening 3 in a plane at a small distance from the carrier 1 is larger than the width of the opening 3 in a plane at a great distance from the carrier 1. The shape of the opening 3 may generally resemble a truncated cone. The uncovered area of the carrier surface in the opening 3 may have any geometrical shape and may in particular be circular, elliptic or polygonal, for example.

The overhanging or re-entrant sidewall may especially be formed with at least one step 4. In the example shown in FIG. 1, there are three steps 4 by way of example. The number of such steps is arbitrary. The edges of the steps 4 may be rounded, and the vertical and horizontal surfaces of the steps 4 may instead be inclined, depending on the applied production process. The heights of the steps 4 can be varied. In other variants of the method, the overhanging or re-entrant sidewall of the opening 3 may be smooth.

The resist layer 2 may especially comprise a negative photoresist. Various methods of structuring negative photoresists to form an opening with an overhanging or re-entrant sidewall are well known in semiconductor technology and need not be further described. Standard lithography can be employed in these methods, for instance.

FIG. 1 shows an example in which the opening 3 has three steps 4 corresponding to four different widths. A largest first width w₁ is present where the sidewall of the opening 3 reaches a first depth d₁, which is equal to the thickness of the resist layer 2. A smaller second width w₂, an even smaller third width w₃ and a smallest fourth width w₄ are present in different upper regions where the resist layer 2 only reaches a second depth d₂, a third depth d₃ and a fourth depth d₄, respectively. By adjusting the depths d₄ independently of each other in order to provide specific widths w₁, w₂, w₃, w₄ of the opening 3, which depend on the distance from the carrier 1, the shape of the lens that is produced by deposition of lens material in the opening 3 can be controlled.

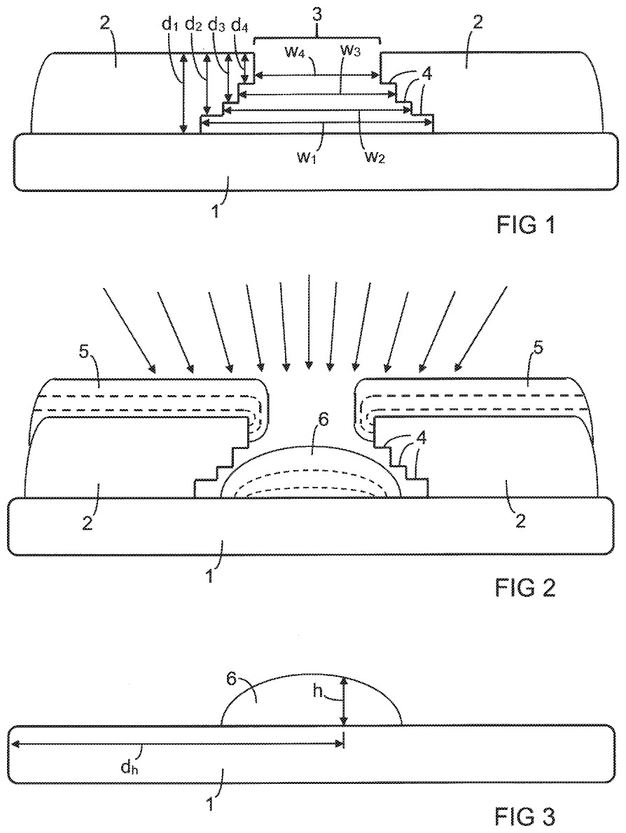

FIG. 2 shows how the lens material 5 is deposited to form a lens 6 in the opening 3 of the resist layer 2. A deposition process that is compatible with a later lift-off process is especially favourable. Evaporation and reactive sputtering are examples of conventional deposition methods that are suitable for the deposition of the lens material 5, but other deposition processes may be applied instead. If a sputtering process is used, for instance, the lens material is sputtered off a target and impinges on the surfaces of the carrier 1 and the resist layer 2. This is indicated by the arrows in FIG. 2. Two intermediate states of the growing lens 6 and the growing layer of further lens material 5 on the resist layer 2 during this deposition process are indicated in FIG. 2 by the broken lines.

The deposition can be controlled to achieve essentially isotropic deposition characteristics, in particular by setting the parameters for the sputter process, for instance. The different widths w₁, w₂, w₃, w₄ of the opening 3, which define different apertures for the deposition of the lens material 5 on the carrier 1, affect the shape of the lens 6 thus obtained, in particular the curvature of its surface. As more and more lens material 5 is deposited in the opening 3, a convex structure is built up according to the different apertures and the isotropic deposition process, until the desired shape of the lens 6 is finally obtained.

FIG. 3 shows the result of a subsequent lift-off process, by which the resist layer 2 is removed together with the lens material 5 that has been deposited on the resist layer 2. The complete lens 6 now stands out on the carrier 1.

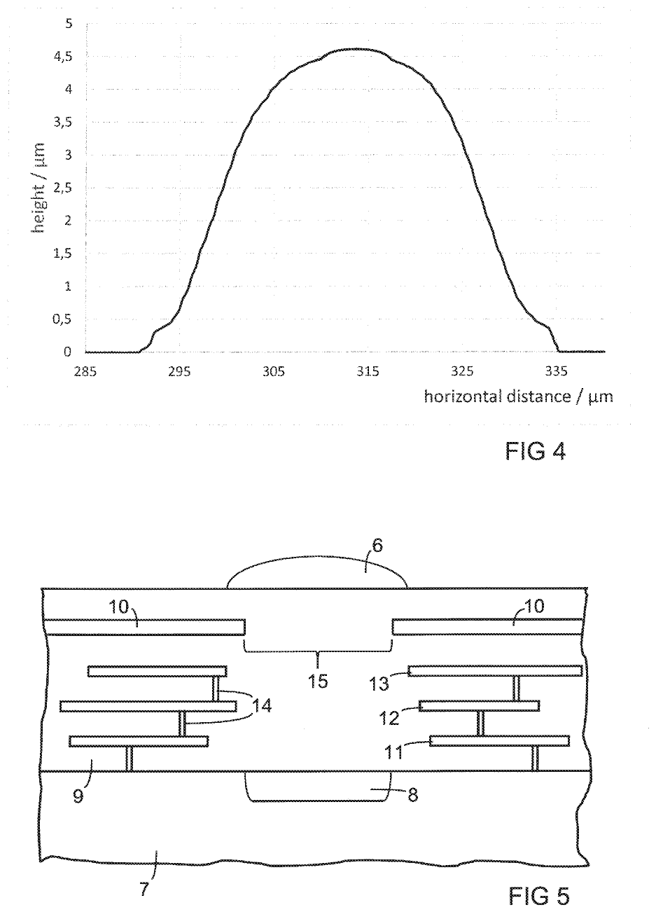

The diagram of FIG. 4 shows the variation of the height h of the lens 6 as a function of the horizontal distance dₕ, as indicated in FIG. 3, for an example of a cylindrical lens 6 produced by the described method, using SiO₂ as the lens material 5.

The lens 6 can be formed in a variety of geometrical shapes, depending on the patterning of the resist layer 2. The lens 6 can at least partly be spherical or cylindrical, for instance. The circumference of the lens 6 can be a circle or a polygon like a hexagon, for instance.

The optical properties of the lens 6 also depend on the lens material 5. SiO₂ can be used as the lens material 5, for instance. Sputtered SiO₂ has a refractive index of about 1.4, shows virtually no dispersion in the visible spectrum and is free of absorption down to 200 nm. Further suitable lens materials are HfO₂, Nb₂O₅ and TiO₂. HfO₂ has a refractive index of about 2.0 and is transparent down to 250 nm. Nb₂O₅ is transparent in the visible and near-infrared spectra and has a refractive index of typically 2.4. The refractive index of TiO₂ is even higher with values up to 2.5, thus providing rather short focal length even for moderately curved lenses. Refractive indices of 2.4 and higher are a prerequisite for use in a clear epoxy package with a refractive index of typically 1.55. The possibility of co-sputtering enables to deposit artificial materials having refractive indices that are not available with a single material. Amorphous silicon or amorphous germanium can also favourably be used for a lens 6 that has to be transparent in the infrared spectrum.

FIG. 5 is a cross section of an example of a semiconductor device with a lens that has been produced by the described method. The semiconductor device comprises an optical component like a photodetector, for instance, which is provided with the lens. Such a semiconductor device can be produced in a CMOS process, for instance. In the example according to FIG. 5, the semiconductor device has a semiconductor substrate 7 with a basic doping, which is provided with a doped region 8 of the opposite type of conductivity in order to form the pn-junction of a photodiode. If the semiconductor substrate 7 has a basic p-type conductivity, for instance, the doped region 8 may be an n-well. An intermetal dielectric 9 is applied on or above the semiconductor substrate 7, and metal layers are embedded in the intermetal dielectric 9 to form a wiring.

FIG. 5 schematically shows a first metal layer 11, a second metal layer 12, a third metal layer 13 and vertical interconnections 14 between the metal layers, which do not cover the photodiode. A passivation layer 10 may be arranged in or above the intermetal dielectric 9. The passivation layer 10 may comprise an opening 15 above the photodiode, especially if the passivation layer 10 comprises a nitride of the semiconductor material, in order to avoid interferences. The passivation layer may be planarized by a further layer, which may comprise the same dielectric material as the intermetal dielectric 9, as in the example shown in FIG. 5.

The described method has the advantage that it enables to manufacture microlenses from inorganic material in a relatively simple and cost effective way, which is compatible with standard CMOS processes. The method is suitable for the application of lens materials that cover a wide range of the electromagnetic spectrum and provide high refractive indices. Furthermore, the described method enables to produce lenses of different materials and shapes on the same substrate. Diameters of the lens can be in the range from a few microns to typically about 80 μm. Depending on the lens geometry, very small spacings between the lenses can be achieved, especially if a two-step method is used for the deposition. The alignment of the microlenses to the substrate is more accurate if the described method is applied instead of conventional methods of producing microlenses. The comparatively high integration density that is achieved by this method facilitates the additional deposition of coatings like anti-reflective coatings, for instance on a plurality of microlenses on the same substrate.

1. A method for manufacturing a microlens, comprising:
providing a carrier,
applying a resist layer on the carrier,
forming an opening with an overhanging or re-entrant sidewall in the resist layer, the carrier being uncovered in the opening,
depositing a lens material, thus forming a lens on the carrier in the opening, and
removing the resist layer.

2. The method of claim 1, wherein the resist layer comprises a negative photoresist.

3. The method of claim 1, wherein the overhanging or re-entrant sidewall is formed to comprise at least one step, which provides different widths (w₁, w₂, w₃, w₄) of the opening in regions of different depths (d₁, d₂, d₃, d₄) of the resist layer.

4. The method of claim 3, wherein the overhanging or re-entrant sidewall is formed to comprise a plurality of steps.

5. The method of claim 1, wherein the lens material is deposited by evaporation.

6. The method of claim 1 to wherein the lens material is deposited by sputtering.

7. The method of claim 1, wherein the lens material is an inorganic material.

8. The method of claim 1, wherein the carrier comprises a semiconductor substrate and a dielectric on the semiconductor substrate, and the resist layer is applied on the dielectric.

9. The method of claim 8, wherein the dielectric comprises an intermetal dielectric, in which metal layers are embedded.

10. The method of claim 9, wherein the dielectric further comprises a passivation layer, which is formed on or in the intermetal dielectric, the lens being formed above an opening of the passivation layer.

11. The method of claim 1, wherein the lens material comprises an oxide of a metal.

12. The method of claim 1, wherein the lens material comprises at least one oxide selected from the group consisting of SiO₂, HfO₂, Nb₂O₅ and TiO₂.

13. The method of claim 1, wherein the lens material is amorphous silicon or amorphous germanium.
